(19) United States
(12) Patent Application Publication
(10) Pub. No.: US 2016/0247919 A1
(43) Pub. Date: Aug. 25, 2016

(54) CHANNEL LAST REPLACEMENT FLOW FOR BULK FINFETS

(71) Applicant: GLOBALFOUNDRIES INC., Grand Cayman (KY)

(72) Inventor: Murat Kerem AKARVARDAR, Saratoga Springs, NY (US)

(73) Assignee: GLOBALFOUNDRIES INC., Grand Cayman (KY)

(21) Appl. No.: 14/628,967

(22) Filed: Feb. 23, 2015

(51) Int. Cl. H01L 29/78; H01L 21/3105; H01L 29/165; H01L 29/66; H01L 29/16; H01L 29/161

(52) U.S. Cl. CPC H01L 29/7848; H01L 29/16; H01L 29/161; H01L 29/165; H01L 29/7851; H01L 29/6656; H01L 29/66545; H01L 29/6681; H01L 21/31051

(57) ABSTRACT

There is set forth herein a method including patterning a fin on a substrate of a semiconductor structure, forming dielectric material over the substrate, performing a process for removing material from a fin to define a cavity at a channel region of the fin, and forming a replacement semiconductor material formation at the channel region.

### TECHNICAL FIELD

The present invention relates to a semiconductor fin structure, and more particularly a semiconductor structure having replacement semiconductor material.

### BACKGROUND OF THE INVENTION

According to a FinFET semiconductor structure architecture, fins can be formed that extend upwardly from a substrate main body. In one commercially available form, a substrate can have various sections recessed to define fins. FinFET semiconductor structures can have one or more active region. An active region can include one or more fins. Active regions of a semiconductor structure can be separated by isolation regions.

Commercially available FinFETs can be formed in part of silicon. Alternative materials have been proposed for fabrication of FinFETS. In one aspect alternative materials can feature improved mobility over silicon. Semiconductor structure having germanium (Ge) and III-V materials have been proposed.

### BRIEF DESCRIPTION

There is set forth herein a method including patterning a fin on a substrate of a semiconductor structure, forming dielectric material over the substrate, performing a process for removing material from a fin to define a cavity at a channel region of the fin, and forming a replacement semiconductor material formation at the channel region.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a method illustrating fabrication of a FinFET device structure;

FIG. 2 is a perspective view of a semiconductor structure in an intermediary fabrications stage after formation of fins;

FIG. 3 is a perspective view of a semiconductor structure in an intermediary fabrication stage after patterning of an isolation trench;

FIG. 4 is a perspective view of a semiconductor structure in an intermediary fabrication stage after formation of dielectric material over the semiconductor structure and planarization;

FIG. 5 is a perspective view of a semiconductor structure in an intermediary fabrication stage after formation of a dummy gate stack, which can include dummy gate oxide, a polysilicon dummy gate, and silicon nitride hard mask, on a planar surface coplanar with the top of the fins;

FIG. 6 is a perspective view of a semiconductor structure in an intermediary fabrication stage after patterning of the dummy gate stack;

FIG. 7 is a perspective view of a semiconductor structure in an intermediary fabrication after recessing of dielectric material and revealing the fins except under the gate;

FIG. 8 is a perspective view of a semiconductor structure in an intermediary fabrication stage after spacer silicon nitride deposition and anisotropic spacer etch;

FIG. 9 is a perspective view of a semiconductor structure in an intermediary fabrication stage after formation of source-drain regions;

FIG. 10 is a perspective view of a semiconductor structure in an intermediary fabrication stage after formation of dielectric material over the entire structure and its planarization to enable coplanarity with the top of a hard mask;

FIG. 11 is a perspective view of a semiconductor structure in an intermediary fabrication stage after removal of nitride hard mask and exposure of a polysilicon layer;

FIG. 12 is a perspective view of a semiconductor structure in an intermediary fabrication stage after removal of polysilicon;

FIG. 13 is a perspective view of a semiconductor structure in an intermediary fabrication stage after formation of cavity in a channel region by recessing the semiconductor fin;

FIG. 14 is a perspective view of a semiconductor structure in an intermediary fabrication stage after selectively growing a replacement semiconductor material within the channel cavity;

FIG. 15 is a perspective view of a semiconductor structure in an intermediary fabrication stage after removal of dielectric material to reveal a channel region defining fins;

FIG. 16 is a cross sectional view taken along line A-A of FIG. 15 illustrating a semiconductor structure having a fabricated field effect transition (FET) having conductive gate material;

FIG. 17 is a graph illustrating a conduction band and a valence band through a source, channel and drain or a FET; and

FIG. 18 is a cross-sectional view illustrating a semiconductor structure having FETs fabricated accordingly to a plurality of different configurations.

### DETAILED DESCRIPTION

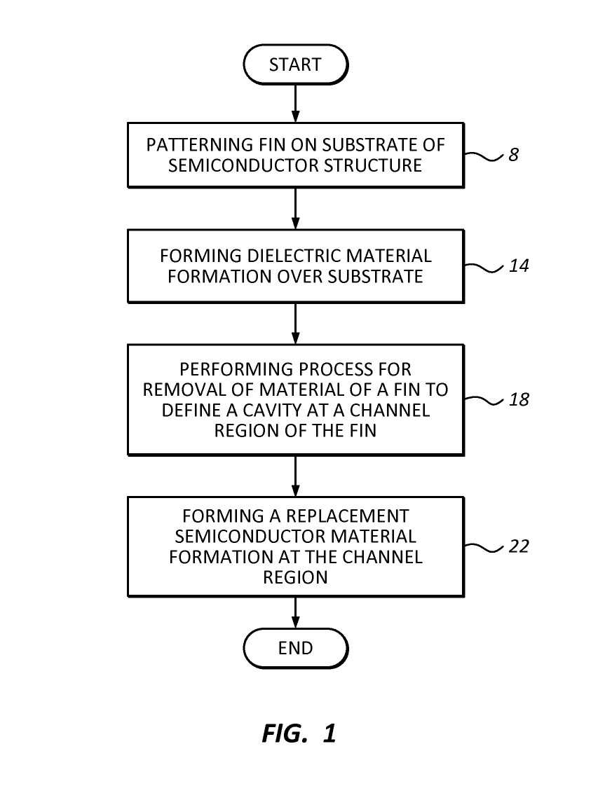

Referring to FIG. 1, there is set forth a method of fabricating a semiconductor structure having replacement semiconductor material at a channel region of the semiconductor structure.

At block 8 there can be performed patterning a fin in a semiconductor structure having a substrate. At block 14 there can be performed forming dielectric material over the substrate. At block 18 there can be performed a process for removal of silicon material of a fin to define a cavity at a channel region of the fin. At block 22 there can be performed forming a replacement semiconductor material formation within the cavity at the channel region. In one embodiment, fabrication processes of blocks 10, 14, 18, and 22 can be performed subsequent to one another.

The method as set forth in FIG. 1 allows for one or more high thermal budget process to be performed prior to the forming of a replacement semiconductor material formation at block 22. The replacement semiconductor material formation is thus not degraded by the one or more high thermal budget process. The method as set forth in FIG. 1 also allows for one or more cleaning process to be performed prior to the forming of a replacement semiconductor material formation at block 22. The replacement semiconductor material formation is thus not degraded by the one or more cleaning process.

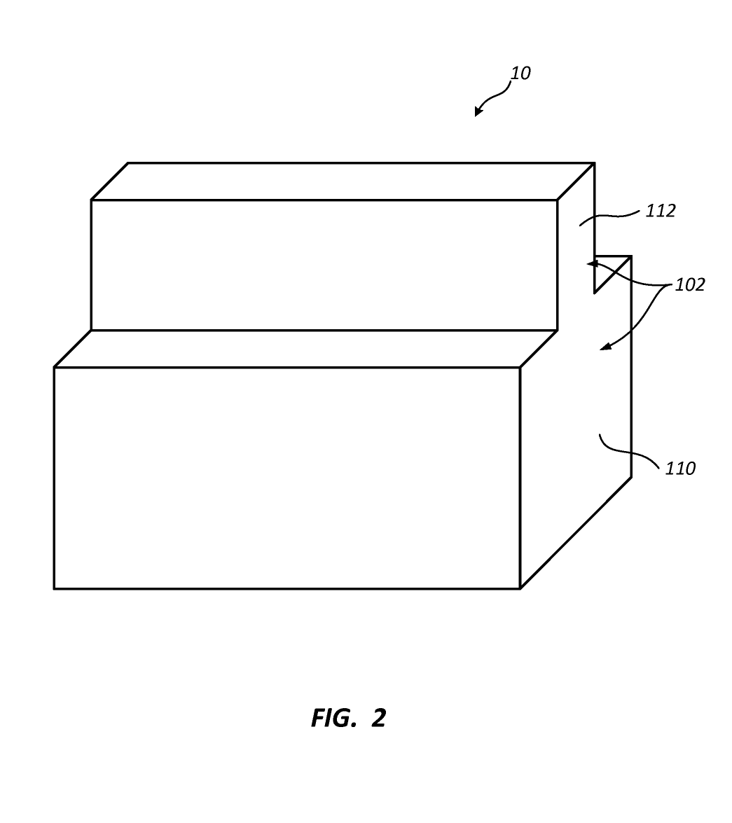

Further aspects of the method set forth in reference to FIG. 1 in one specific example are described in reference to FIGS. 2-15.

Referring to FIG. 2, there is illustrated semiconductor structure 10 having a main body section 110 and a fin section including a plurality of fins of which a representative fin 112 is shown. Substrate 102 in one embodiment can be formed of silicon (Si). In one embodiment, fins 112 of substrate 102 can be patterned at block 8 by selectively removing sections of silicon of substrate 102. In one embodiment, patterning of fins 112 can involve epitaxially growing fins on main body section 110 of substrate 102.

With fins 112 formed as shown in FIG. 2, dielectric material can be formed over substrate 102 which can have main body section 110 and fins. Prior to forming dielectric material over substrate 102, one or more isolation trench such as isolation trench 116 can be formed in substrate 102 separating active regions of substrate 102.

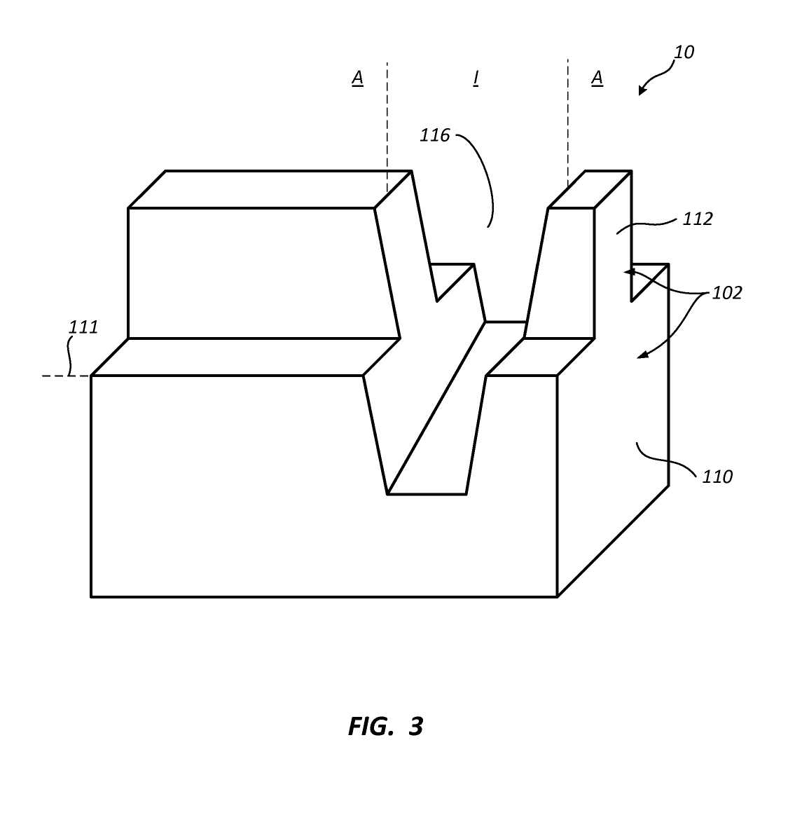

Referring to FIG. 3, FIG. 3 illustrates semiconductor structure 10 as shown in FIG. 2 after patterning of isolation trench 116 (block 8). Isolation trench 116 can extend below a top elevation 111 of main body section 110 of substrate 102. In another embodiment isolation trench 116 may not extend below a top elevation 111 of main body section 110 of substrate 102. Semiconductor structure 10 can have a plurality of active regions A and plurality of isolation region I as are depicted in FIG. 3. Isolation region I can have trenches such as trench 116 shown in FIG. 3. In one embodiment, isolation region I can separate FET regions of opposite polarity. In one embodiment an active region A left of isolation region I can be an nFET region and an active region A right of isolation region I can be a pFET region. In one embodiment an active region A left of isolation region I can be pFET region and an active region A right of isolation region I can be a nFET region.

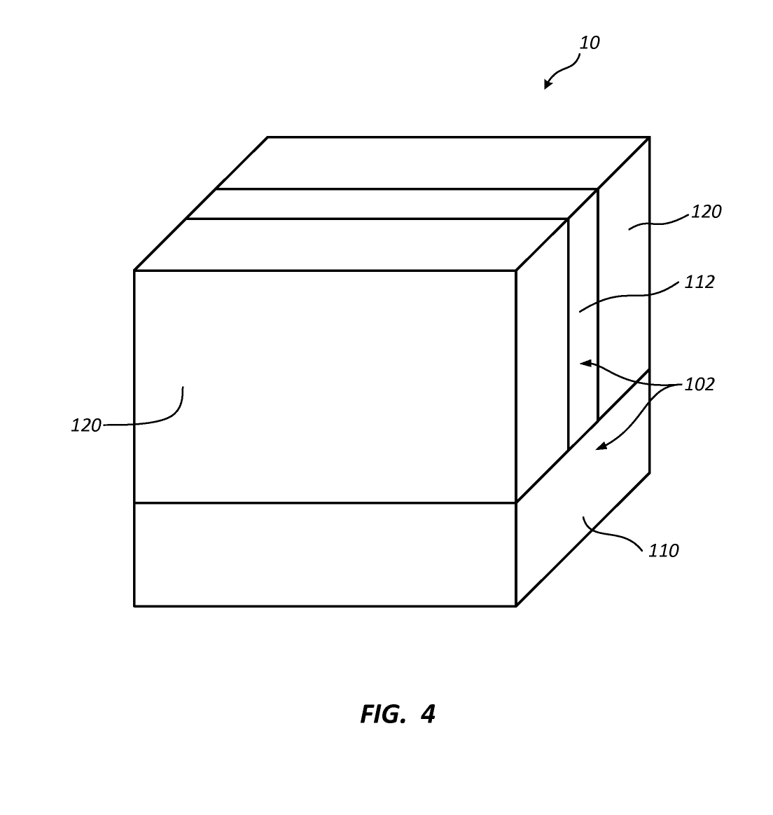

FIG. 4 illustrates semiconductor structure 10 in an active region A of semiconductor structure 10 as shown in FIG. 3 after formation at block 14 (FIG. 1) of layer 120 to form dielectric material over substrate 102. Layer 120 can be formed over substrate 102 including within trench 116 (shown in FIG. 3) which trench 116 can separate active regions of a semiconductor structure 10. Layer 120 can be formed of dielectric material, e.g., oxide. As shown in FIG. 4, layer 120 can be planarized so that a top elevation of layer 120 has a planarized common elevation with a top elevation of fin 112. Layer 120 can be initially formed conformally over fins, e.g., fin 112 and within trenches, e.g., trench 116 prior to planarization of layer 120.

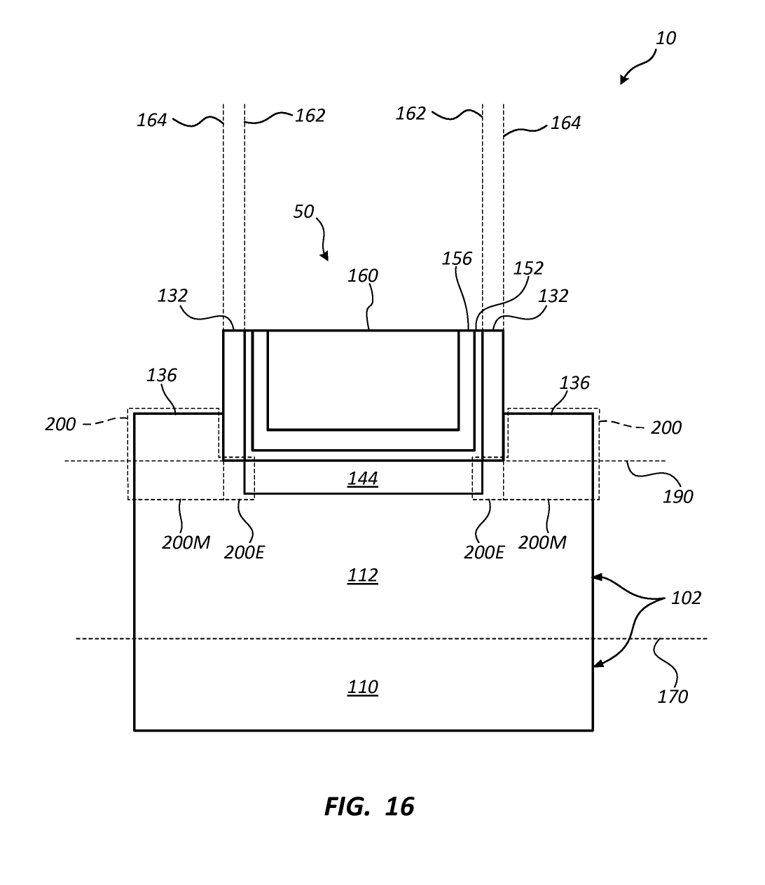

At block 18 (FIG. 1) there can be performed a process for removal of material of fin 112 to define a cavity in a channel region of semiconductor structure 10. A channel region of fin 112 in an intermediary fabrication stage can refer to a volume that defines a channel when a field effect transistor (FET) having conductive gate material is fabricated (e.g., as shown and described in reference to FIG. 16 herein). Implementation of block 18 (process for removal of material of a fin to define a cavity at a channel region of a fin) in one embodiment is described herein, in reference to FIGS. 4-13.

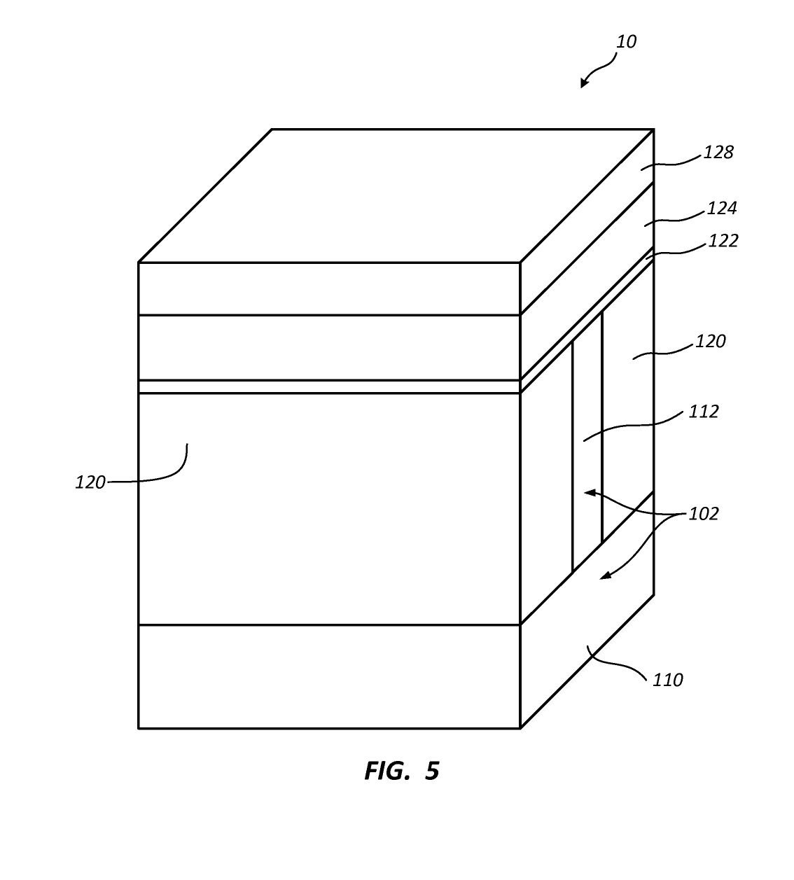

FIG. 5 illustrates the semiconductor structure 10 as shown in FIG. 4 after formation of layer 122 and layer 124 over layer 120 and fin 112. Further referring to FIG. 5, FIG. 5 illustrates formation of layer 128 over layer 124 and layer 122. Layer 122 in one embodiment can be formed of dielectric material, e.g., oxide. Layer 124 in one embodiment can be formed of amorphous polysilicon. Layer 128 in one embodiment can be formed of a nitride, e.g., silicon nitride (SiN). In one aspect as shown in the embodiment of FIG. 5, layer 124 and layer 128 are deposited without the top portion of the fins being revealed such that they extend horizontally in a direction parallel to a planarized top surface of layer 120 and fin 112. It will be seen that forming layer 124 and layer 128 as shown in FIG. 5 allows a template of fin 112 to be preserved until a replacement metal gate process. It is seen in reference to FIG. 5 that formation of layer 124 and 128 in a manner that sidewalls of fin 112 are not revealed and with layer 120 about fin 112 remaining allows a cavity having the shape of fin 112 to be formed after formation of layer and layer 128 thus preserving a template of fin 112. A cavity having the shape of fin 112 in accordance with the flow diagram of FIG. 1 (by completion of block 18) can be formed just prior to performance of block 22. Preserving a template of fin 112 allows one or more high temperature process to be performed prior to formation of a replacement semiconductor formation at block 22.

Because a volume occupied by a section of layer 124 can later be occupied by conductive gate material, layer 124 can be regarded as a dummy gate.

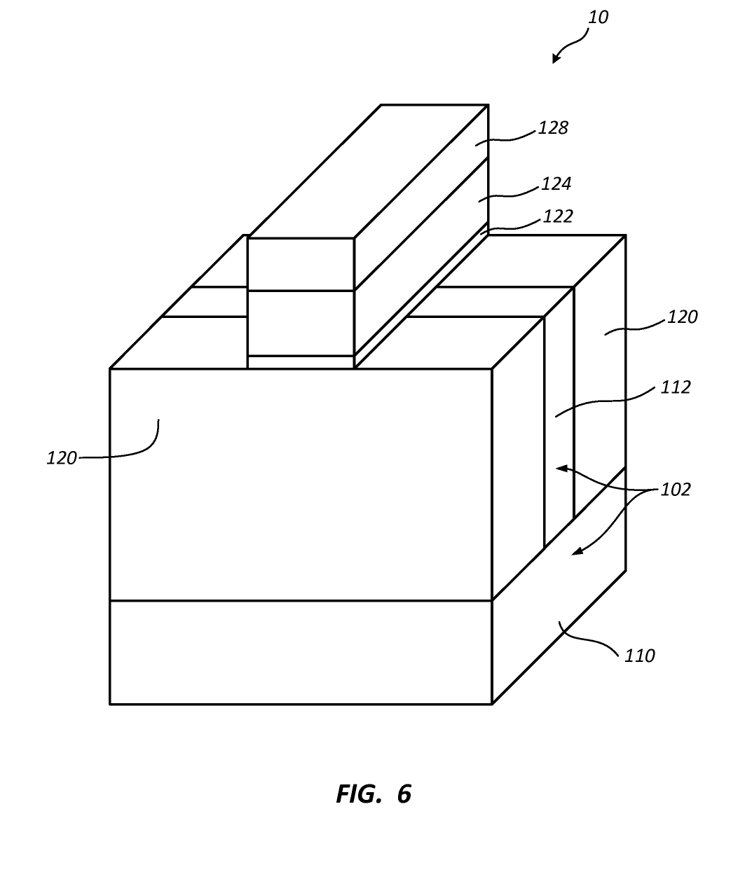

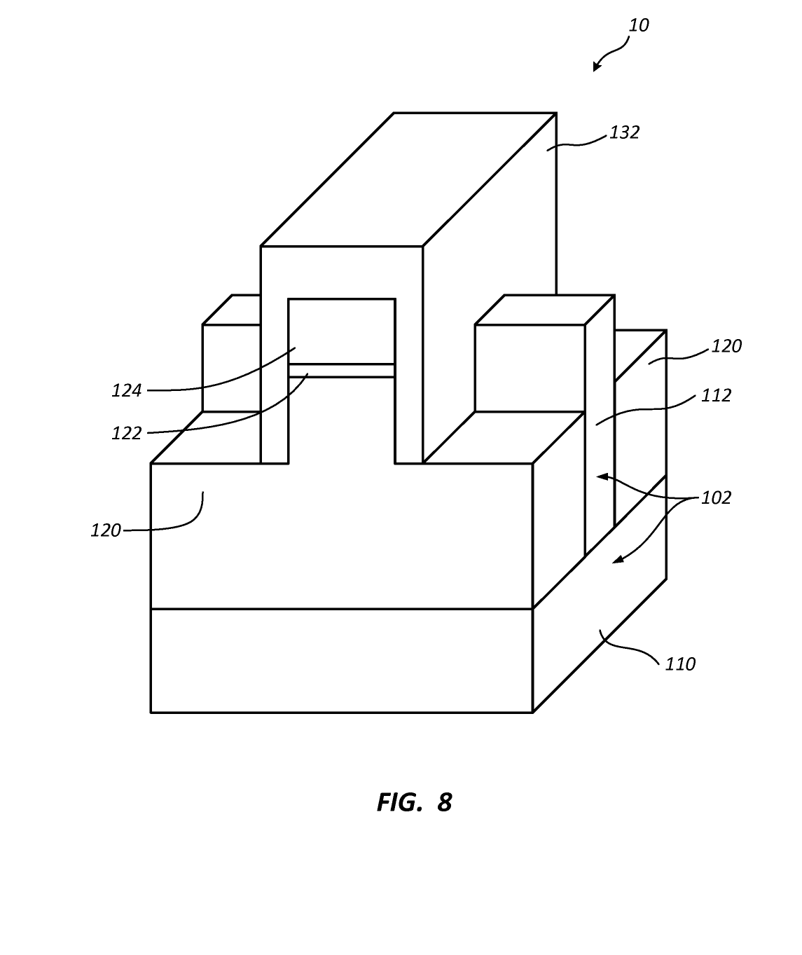

FIG. 6 illustrates the semiconductor structure 10 as shown in FIG. 5 after patterning of layer 122 layer 124 and layer 128. Patterning of layer 122, layer 124 and layer 128 allows shaping of gate spacers defined by layer 132 to be formed over layer 128 as is explained in reference to FIG. 8.

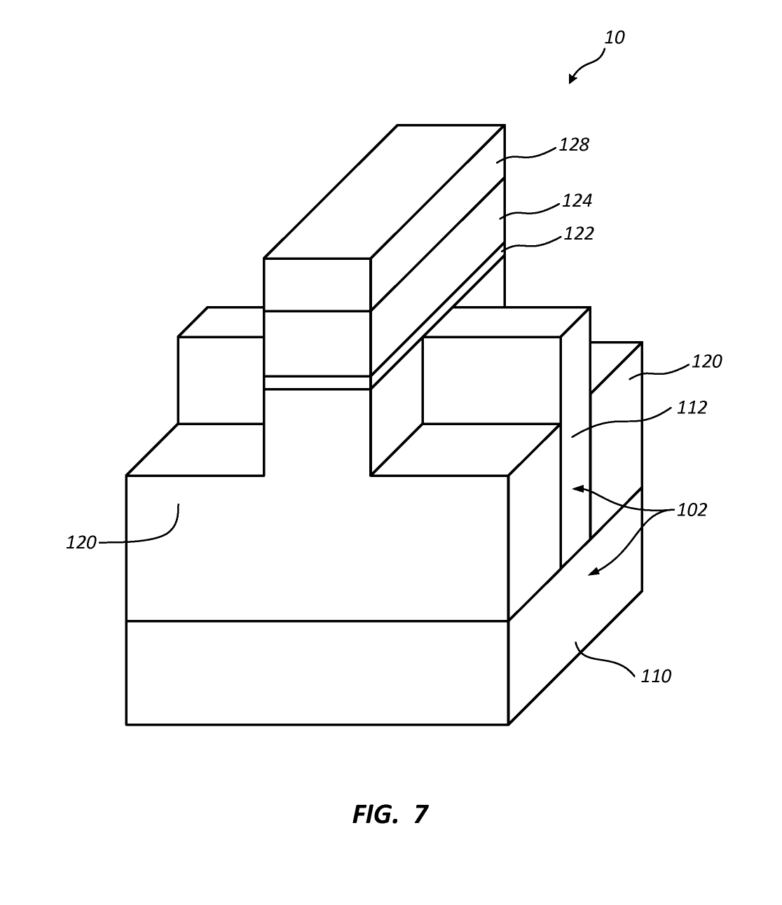

Prior to formation of a layer that defines gate spacers a process can be performed for fabrication of a source-drain by revealing a fin at a source-drain region of a fin. Referring to FIG. 7, a process for fabrication of a source-drain can be performed prior to completion of block 18 (process for removal of material of a fin to define a cavity of a channel region of the fin). FIG. 7 illustrates the semiconductor structure 10 as shown in FIG. 6 after anisotropic removal of material from layer 120. Referring to FIG. 7 the anisotropic recess of the material from layer 120 reveals fin 112 at an outside of a gate region of a fin, in a source-drain region of a fin 112. A gate region of a fin can refer to a volume of a fin 112 occupied by a gate of a fabricated FET having conductive gate material, e.g., as shown in FIG. 16. A source-drain region of a fin 112 can refer to a volume of a fin 112 occupied by a source-drain of a fabricated FET having conductive gates material, e.g., as shown in FIG. 16.

Referring to FIG. 8, FIG. 8 illustrates the semiconductor structure 10 as shown in FIG. 7 after formation of layer 132 by conformal deposition and anisotropic etch. Layer 132 can define gate spacers illustrated by sections of layer 132 disposed side adjacent to layers 122, 124, and 128. Layer 132 in one embodiment can be formed of a nitride, e.g., silicon nitride.

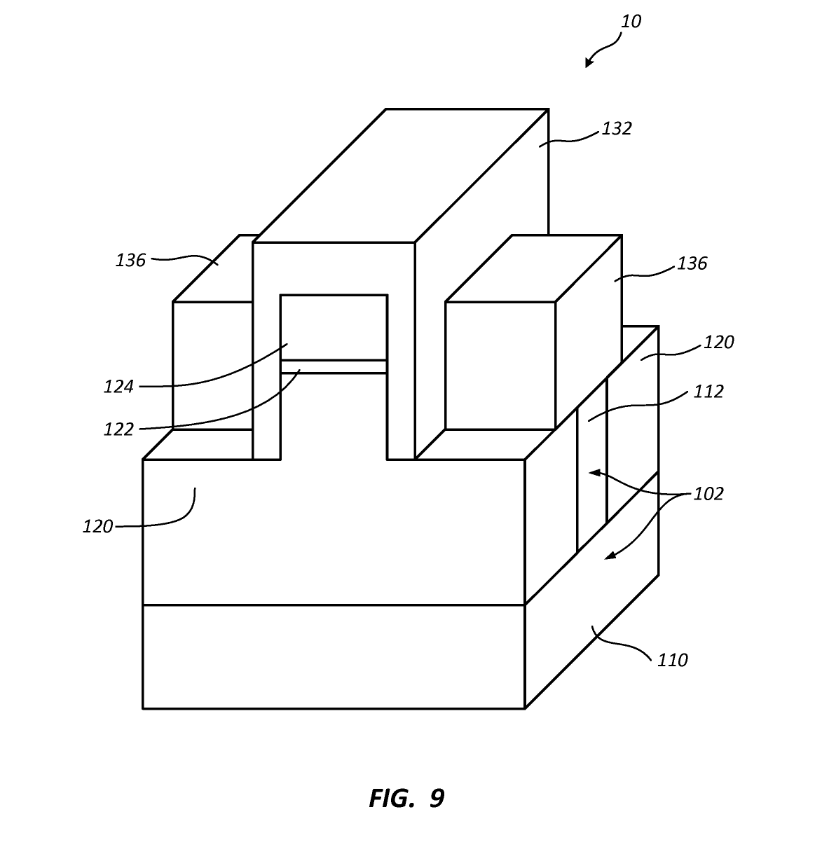

In one embodiment, source-drain material formation as set forth herein (e.g., as shown in FIG. 9 illustrating source-drain material formation 136) can be fabricated prior to completion of a process at block 18 of a process for removal of material of fin to define cavity 142 in a channel region fin 112 and prior to formation of a replacement semiconductor material formation at block 22. In one embodiment, source-drains of a fabricated FET 50 (FIG. 16) having gate conductive material can be fabricated prior to completion of a process at block 18 a process for removal of material of fin 112 to define a cavity 142 in a channel region of a fin 112 and prior to formation of replacement semiconductor material formation at block 22. Fabrication of source-drains of semiconductor structure 10 can include one or more high temperature process, in particular dopant activation anneals. Performing fabrication of source-drains having source-drain material formation 136 prior to completion of block 18 and block 22 can avoid exposure of replacement semiconductor material formation to one or more high thermal budget process.

A fabrication of source-drain material formations can be regarded as being commenced with the performance of a process as explained in reference to FIG. 7 wherein fin 112 can be revealed in source-drain regions thereof. Referring to FIG. 9, FIG. 9 illustrates the semiconductor structure 10 as shown in FIG. 8 after selective epitaxial growth of the source-drain material formations 136. In one embodiment, a top surface of fin 112 can be recessed prior to growing of source-drain material formations 136 to yield an embedded source-drain structure. In one embodiment, an area of fin 112 which can be recessed prior to growing of source-drain material formation 136 can include an area of fin 112 under gate spacers defined by layer 132. In another embodiment, source-drain material formations 136 can be grown on a top surface and sidewalls of fin 112. Material of source-drain material formations 136 grown on material of fin 112 can be, e.g., silicon or silicon germanium.

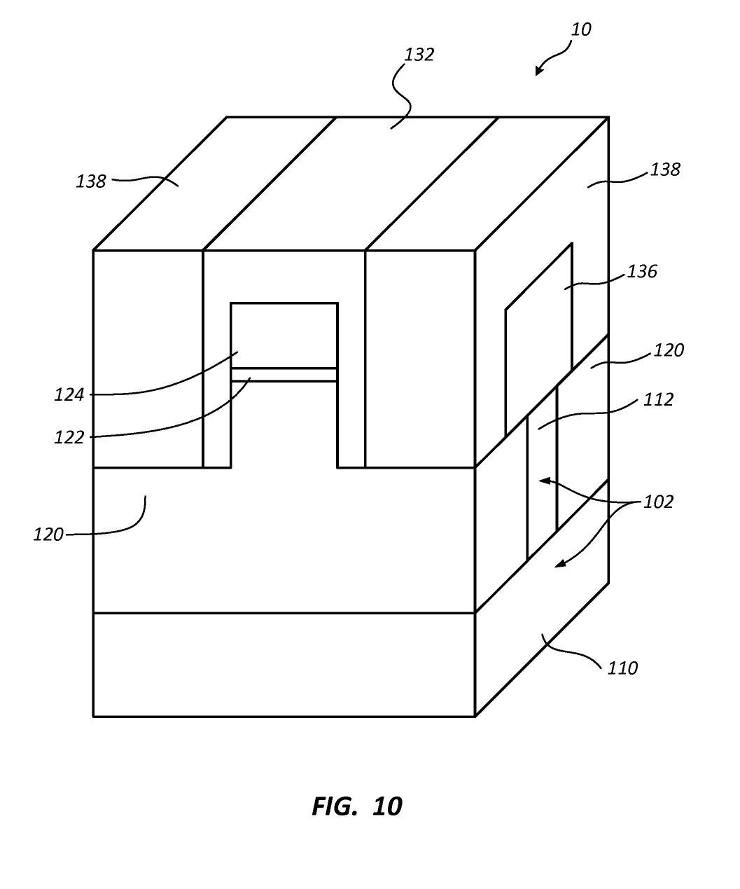

FIG. 10 illustrates the semiconductor structure 10 as shown in FIG. 9 after formation of layer 138 over source-drain material formations 136. Layer 138 can be formed of a dielectric material, e.g., an oxide. Layer 138 can be planarized as shown in FIG. 10 so that a top surface of layer 138 is co-planar with a top surface of layer 132.

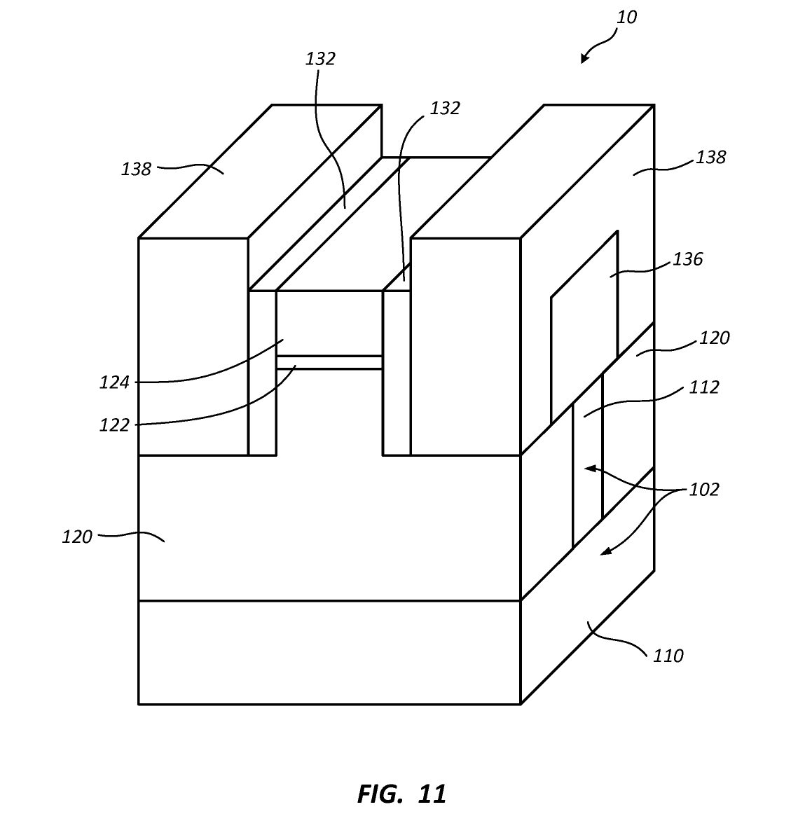

FIG. 11 illustrates the semiconductor structure 10 as shown in FIG. 10 after removal of material of layer 132. Removal of material of layer 132 can reveal material of layer 124 for removal. Layer 124 can be formed of polysilicon.

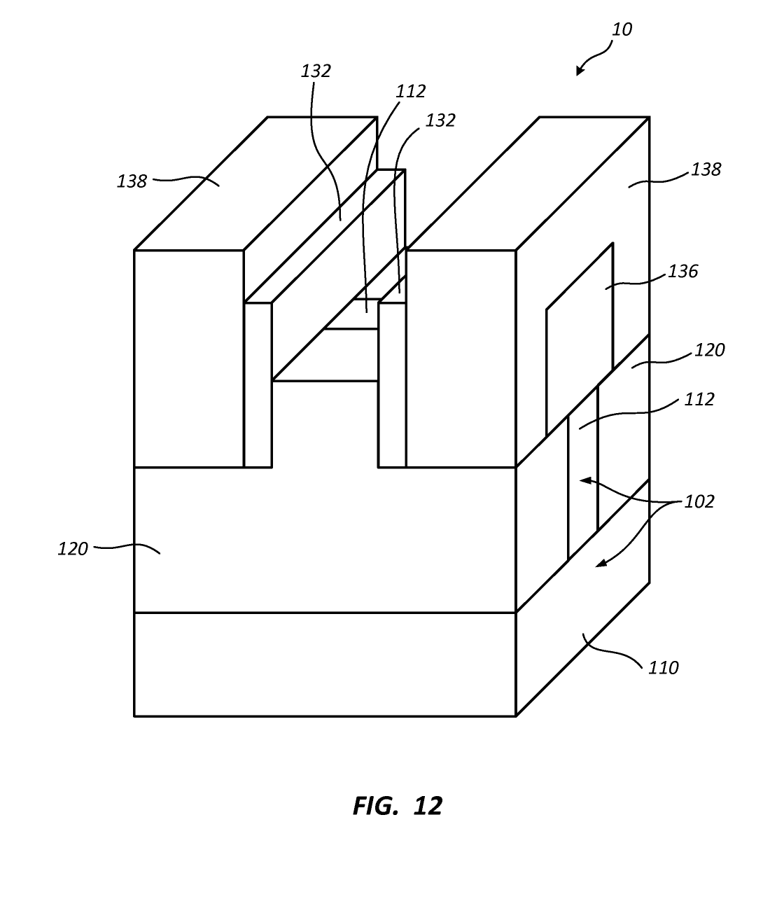

FIG. 12 illustrates the semiconductor structure 10 as shown in FIG. 11 after removal of material of layer 124 and layer 122. After removal of material of layer 124 and layer 122, a top surface of fin 112 can be revealed as shown in FIG. 9 in an area between gate spacers defined by layer 132. Fin 112 in the stage depicted in FIG. 12 can be formed of silicon.

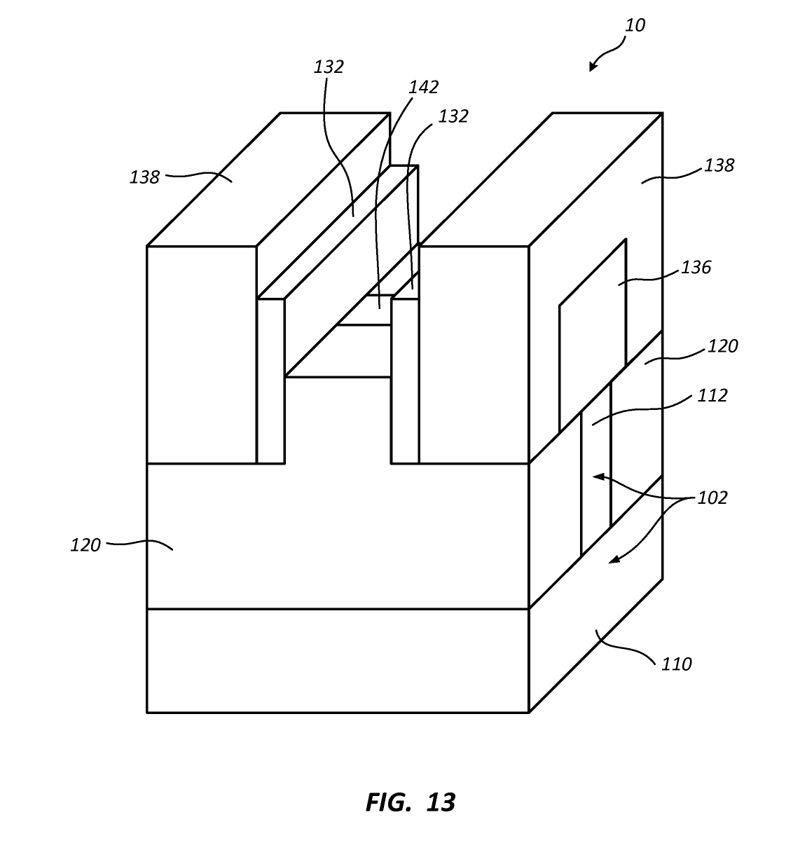

FIG. 13 illustrates the semiconductor structure 10 as shown in FIG. 12 after performance of a material removal stage for removal of material from fin 112 to define a cavity 142 in a channel region of fin 112 aligned to gate spacers defined by layer 132. The material removed from fin 112 can be silicon. Cavity 142 can be defined at a volume of semiconductor structure 10 occupied by fin 112 prior to the fabrication stage depicted FIG. 13. A channel region of a fin 112 can refer to a volume of semiconductor structure 10 occupied by a channel of a fabricated FET 50 having conductive gate material, e.g., as shown in FIG. 16.

In one embodiment performance of a material removal stage for removal of material from fin 112 to define cavity 142 at a channel region of fin 112 as shown in FIG. 13 can be performed using reactive ion etching (RIE). RIE can restrict an amount of silicon removal to an area substantially delimited by vertical planes 162 bordering an interior of spacers defined by layer 132 which may provide advantages in certain embodiments.

Using an alternative etching method which may provide advantages in certain other embodiments material removal from fin 112 may be more likely to be restricted to an area substantially delimited by vertical planes 164 bordering an external surface of spacers defined by layer 132. In either case, cavity 142 defined by material removal can be regarded as being restricted to an area aligned to gate spacers defined by layer 132.

In one aspect of performance of block 18 (perform process for removal of material of a fin at a channel region) performance of block 18 can include performance of a material removal stage for selectively removing material of a fin to define a cavity at a channel region of a fin in an area aligned to gate spacers which can be defined by layer 132.

In one aspect of performance of block 18 (perform process for removal of material of a fin at a channel region) performance of block 18 can include performance of a material removal stage for selectively removing material of a fin to define a cavity at a channel region of a fin 112 in an area aligned to gate spacers which can be defined by layer 132 substantially restricted to an area between vertically extending planes 162 (FIG. 16) bordering an interior of sidewalls defined by layer 132.

In one aspect of performance of block 18 (perform process for removal of material of a fin at a channel region) performance of block 18 can include performance of a material removal stage for selectively removing material of a fin to define a cavity at a channel region of a fin in an area aligned to gate spacers which can be defined by layer 132 substantially restricted to an area between vertically extending planes 164 (FIG. 16) bordering an exterior of sidewalls defined by layer 132.

In one aspect of performance of block 18 (perform process for removal of material of a fin to define a cavity at a channel region) performance of block 18 can include performance of a material removal stage for removal of material of a fin at a channel region of fin 112 without removal of material of a fin at source-drain region of a fin 112. A source-drain region of a fin 112 in an intermediary fabrication stage can refer to a volume occupied by a defined source-drain of a fabricated FET having conductive gate material, e.g., as shown in FIG. 16 as set forth herein.

In one aspect of performance of block 18 (perform process for removal of material of a fin at a channel region) performance of block 18 can include fabricating of source-drain material formations 136 for fabricating of source-drains of a semiconductor structure 10 (with or without recessing of a fin, e.g., as depicted in FIG. 9) prior to completion of block 18.

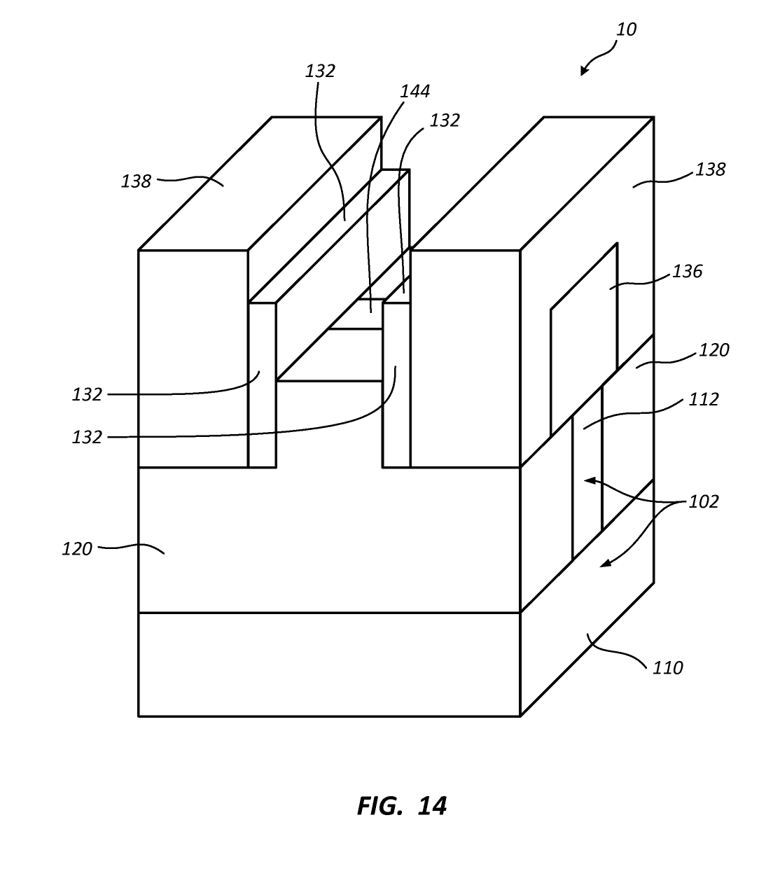

FIG. 14 illustrates performance of block 22 (formation of replacement semiconductor material formation). FIG. 14 illustrates the semiconductor structure 10 as shown in FIG. 13 after selective epitaxial growth of semiconductor material to form replacement semiconductor material formation 144 within cavity 142 (FIG. 13). Semiconductor material formation 144 can include, e.g., alloys or compounds, e.g., silicon germanium (SiGe), silicon carbide (SiC), germanium (Ge), or Group III-V materials. Forming of semiconductor material formation 144 can result in reconstruction of fin 112.

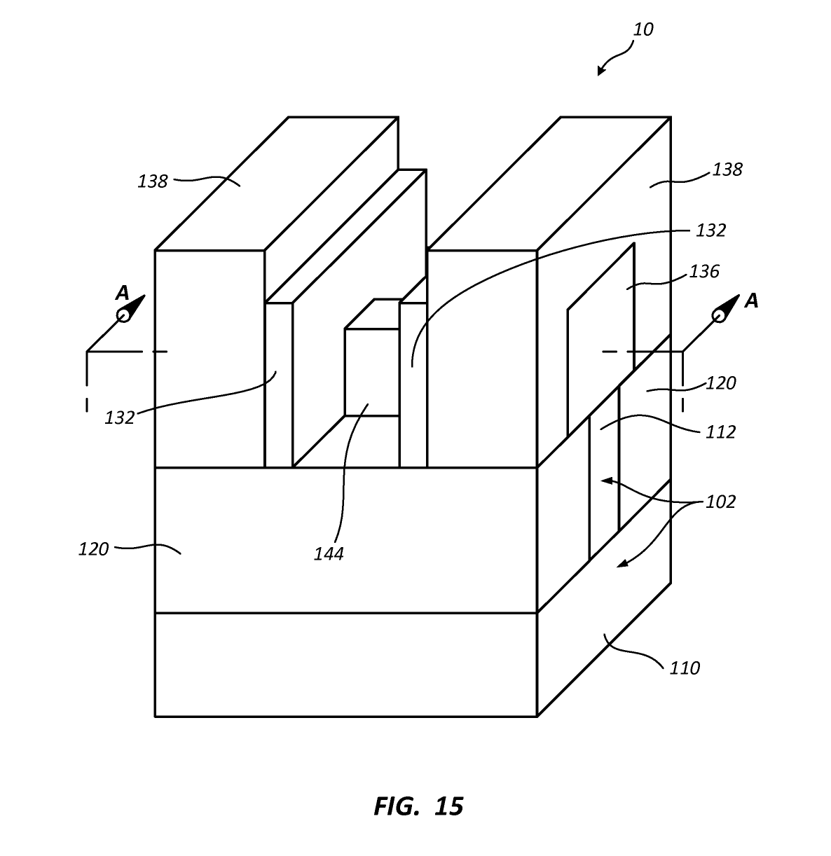

FIG. 15 illustrates the semiconductor structure 10 as shown in FIG. 14 after removal of material from layer 120 about replacement semiconductor material formation 144 in order to reveal fin 112 in an area of replacement semiconductor material formation 144.

Replacement semiconductor material formation 144 defines a channel of a fabrication FET 50, e.g., shown in FIG. 16. Forming formation 144 in the stage depicted at FIG. 14 can avoid exposure of formation 144 to high thermal and/or harsh cleaning processes. For example, as depicted at block 14 (FIG. 1) forming dielectric material in one embodiment can include a shallow trench isolation (STI) anneal which anneal can be performed at an annealing temperature of between, e.g., 1000 deg. Celsius and about 1200 deg. Celsius for a period of about 10 min. to about 120 min. in one embodiment. A well activation annealing in one embodiment can be performed at a temperature of between about 900 deg. Celsius to about 1100 deg. Celsius for a period of from about 1 second to about 10 seconds. A source-drain activation anneal in one embodiment can be performed at from about 900 deg. Celsius to about 1050 deg. Celsius for a period of up to about 5 seconds. Harsh cleaning processes that can be performed prior to formation of formation 144 can include post fin formation cleaning (using, e.g., SC1, SC2 sulfuric peroxide and HFEG, fin reveal cleaning (using, e.g., Siconi, COR or DHF), post gate etch cleaning (using, e.g., SC1, SC2, and sulfuric peroxide), post spacer etch cleaning (using, e.g., SC1, SC2, sulfuric peroxide, and epi preclean (using, e.g., Siconi and H2 prebake).

Referring to FIG. 16, fabrication of a field effect transistor (FET) 50 can be completed with formation of one or more layer 152 formed of dielectric material, e.g., high K dielectric material, and one or more layer 156 formed of work function conductive material. One or more layer 160 formed of metallic material can be formed over layer 156 to define a gate capping layer. Elevation 190 as shown in FIG. 16 can be a top elevation of substrate 102 and elevation 170 can be a top elevation of main body section 110 of substrate 102. A fabricated FET 50 as shown in FIG. 16 can include a gate having gate spacers defined by layer 132 one or more layer 152 of dielectric material one or more layer 156 of conductive work function material and one or more layer 160 of capping material. A fabricated FET 50 as shown in FIG. 16 can include source-drains 200. Each source-drain 200 can have a main body section 200M and an extension 200E formed under a spacer defined by layer 132. A FET channel when a gate is active can be defined by replacement semiconductor material formation 144 which semiconductor material formation 144 defines a reconstructed fin 112. In one embodiment a source-drain can be defined entirely by epitaxially grown source-drain material formation 136 if fin 112 recessed below top elevation 190 of substrate 102 including under a spacer defined by layer 132 prior to growing of formation 136. In another embodiment a source-drain 200 can be defined by formation 136 and be a section of doped fin 112 which can be formed of silicon. Such section can encompass one or more of an area of extension 200E or an area of main body section 200M.

The method of FIG. 1 facilitates flexibility in the providing of materials for a channel defined by replacement semiconductor material formation 144 and a source-drain 200 while reducing a risk of degradation to replacement semiconductor material during performance of fabrication processes. In one embodiment, a channel defined by replacement semiconductor material formation 144 can be provided by any replacement semiconductor material selected from the group consisting of silicon germanium (SiGe), silicon carbide (SiC), germanium (Ge), or Group III-V materials and a source-drain 200 can be provided by any material selected from the group consisting of silicon and silicon germanium. In one embodiment a source-drain can include any material selected from the group consisting of silicon (Si) and silicon germanium (SiGe).

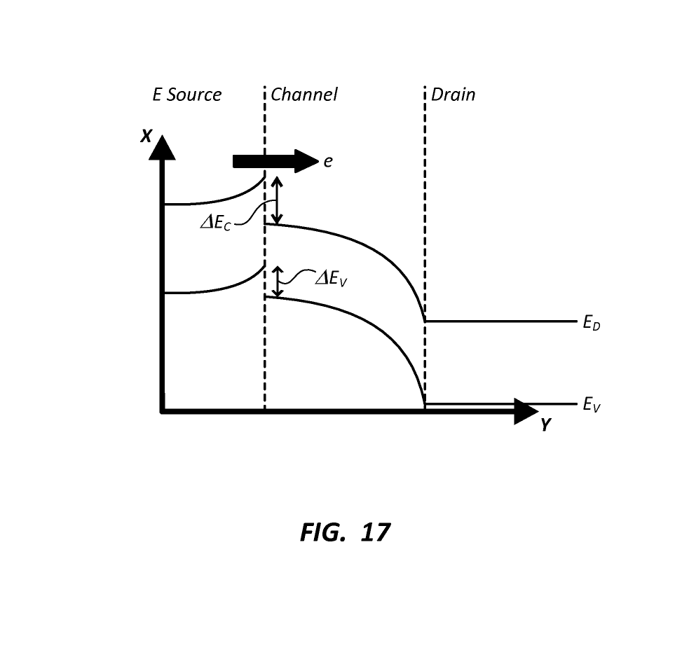

Referring to FIG. 17, performance of a fabricated FET 50 can be optimized for a particular application by providing of a channel and a source of a source-drain 200 so that FET 50 features a particular conduction and valance band offset. FIG. 17 is a graph illustrating conduction band Ec and valence band Ev through a source, channel and drain of a FET 50. By configuring a FET 50 to include a conduction band offset ΔEc between a source and a channel there can be provided a higher electron velocity between a source and a channel. By configuring a FET 50 to include a valence band offset ΔEv between a source and channel there can be provided an increased hole injection velocity between a source and a channel. By providing multiple options for materials defining a channel for FET 50 the method of FIG. 1 facilitates engineering of a FET 50 so that FET 50 can feature a particular band gap that optimizes FET 50 for a particular application.

The method of FIG. 1 can be varied to fabricate FETs having different configurations. The different configurations can be fabricated at different areas of a common substrate 102 of a semiconductor structure 10 on which FETs 50 in different areas of the semiconductor structure 10 can be formed. Referring to FIG. 9, source-drain material formations 136 can be grown on fin 112 to define source-drains 200 of semiconductor structure 10. Prior to growing source-drain material formations 136 on fin 112, fin 112 can be recessed. For providing one exemplary configuration, an area of fin 112 recessed may include a region that defines an extension 200E at a fabricated FET 50 (FIG. 16), which is defined as the fin 112 region under the spacer. For providing another exemplary configuration, an area of fin 112 recessed may not include the extension region. In such a configuration, the extension region is made of the same material as the original material forming fin 112, which can typically be silicon. In one embodiment, source-drain material formation 136 can be formed of silicon. In one embodiment, source-drain material formation 136 can be formed of silicon germanium. Exemplary configurations of semiconductor structure 10 are summarized in Table A.

TABLE A

| | SD | SD | |
|---|---|---|---|
| | main body | Extension | Extent of fin recess prior to |
| Configuration | 200M | 200E | epitaxial growth |
| A | Si | Si | Not under spacer or under |
| | | | spacer |
| B | SiGe | SiGe | Under spacer |
| C | SiGe | Si | Not under spacer |

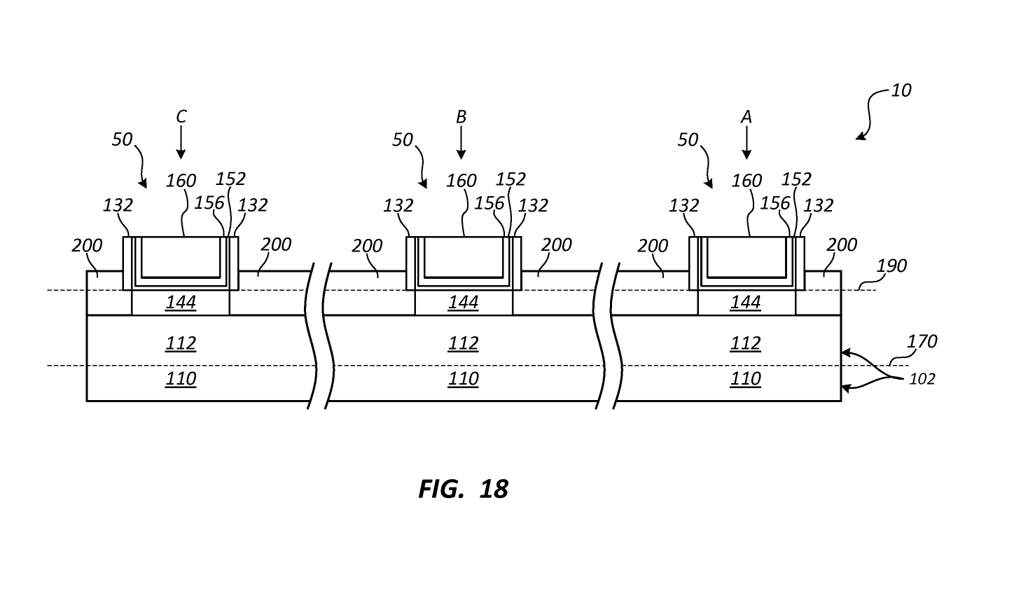

Referring to the Configurations as depicted in Table A, a FET 50 in accordance with Configuration A can include a source-drain main body section 200M formed of silicon and source-drain extension 200E (at an area of a fin aligned to a spacer) formed of silicon. Configuration A can be provided by recessing of fin 112 to an area under a spacer. Configuration A can also be provided by recessing of fin 112 to an area that does not extend to an area under a spacer. Referring further to the Configurations as depicted in Table A, a FET 50 in accordance with Configuration B can include a source-drain main body section 200M formed of silicon germanium and a source-drain extension 200E (at an area of a fin aligned to a spacer defined by layer 132) formed of silicon germanium. Configuration B can be provided by recessing of fin 112 to an area under a spacer defined by layer 132. Referring further to the Configurations as depicted in Table A, a FET 50 in accordance with Configuration A can include a source-drain main body section 200M formed of silicon germanium and a source-drain extension 200E (at an area of a fin aligned to a spacer) formed of silicon germanium. Configuration C can be provided by recessing of fin 112 to an area that does not extend to an under a spacer. A semiconductor structure 10 having a common substrate 102 as depicted in FIG. 18 can be fabricated as set forth herein to include at area A one or more FETs 50 fabricated according to Configuration A, at area B one or more FETs 50 fabricated according to Configuration B and at area C one or more FETs 50 fabricated according to Configuration C. Referring to FIG. 18, elevation 190 can be a top elevation of substrate 102 and elevation 170 can be a top elevation of substrate main body section 110.

Each of the formed layers as set forth herein, e.g., layer 102, layer 120, layer 124, layer 128, layer 132, layer 136, layer 138, layer 144, layer 152, layer 156 and/or layer 160 can be formed by way of deposition using any of a variety of deposition processes, including, for example, physical vapor deposition (PVD), atomic layer deposition (ALD), chemical vapor deposition (CVD), sputtering, or other known processes, depending on the material composition of the layer.

In one example, a protective mask layer as set forth herein, e.g., a mask layers for patterning layer 102, layer 120, layer 124, layer 128, layer 132, layer 136, layer 138, layer 144, layer 152, layer 156 and/or layer 160 as set forth herein may include a material such as, for example, silicon nitride, silicon oxide, or silicon oxynitride, and may be deposited using conventional deposition processes, such as, for example, CVD or plasma-enhanced CVD (PECVD). In other examples, other mask materials may be used depending upon the materials used in semiconductor structure. For instance, a protective mask layer may be or include an organic material. For instance, flowable oxide such as, for example, a hydrogen silsesquioxane polymer, or a carbon-free silsesquioxane polymer, may be deposited by flowable chemical vapor deposition (F-CVD). In another example, a protective mask layer may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB).

Removing material of a layer as set forth herein, e.g., layer 102, layer 120, layer 124, layer 128, layer 132, layer 136, layer 138, layer 144, layer 152, layer 156 and/or layer 160 can be achieved by any suitable etching process, such as dry or wet etching processing. In one example, isotropic dry etching may be used by, for example, ion beam etching, plasma etching or isotropic RIE. In another example, isotropic wet etching may also be performed using etching solutions selective to the material subject to removal.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
patterning a fin on a substrate of a semiconductor;
forming dielectric material over the substrate;
forming gate spacers;
performing a process for removal of material of the fin to define a cavity at a channel region of the fin, wherein the performing comprises aligning sides of the cavity to inner vertical planes of the gate spacers and wherein the cavity directly touches a source and a drain, such that there is an absence of other material between the cavity and the source and drain; and
forming replacement semiconductor material at the channel region.

2. The method of claim 1, wherein the forming dielectric material includes planarizing a dielectric material formation so that a top surface of the dielectric material formation extends in a horizontal plane, and wherein the performing a process includes forming dummy gate stack that extends in a direction parallel to the horizontal plane.

3. The method of claim 1, wherein the performing a process for removal includes forming gate spacers, and performing a material removal stage for selectively removing the material of the fin at a channel region at an area of the fin aligned to the gate spacers.

4. The method of claim 3, wherein the area of the fin aligned to the gate spacers include an area under the gate spacers.

5. The method of claim 1, wherein performing a process for removal includes removing material selectively from the channel region.

6. The method of claim 1, wherein the performing a process includes performing a material removal stage for removing material of the fin selectively from the channel region without removing material from a source-drain region of the fin.

7. The method of claim 1, wherein the replacement semiconductor material is selected from the group consisting of silicon germanium (SiGe), silicon carbide (SiC), germanium (Ge), and Group III-V materials.

8. The method of claim 1, wherein the method includes commencing fabrication of a source-drain prior to completion of the performing a process for removal.

9. The method of claim 1, wherein the method includes forming a source-drain material formation prior to the forming replacement semiconductor material.

10. The method of claim 1, wherein the method includes selecting material for a channel and a source for achieving a desired conduction band or valence band offset.

11. The method of claim 1, wherein the method includes selecting material for a channel and a source for achieving a desired strain state in the channel.

12-19. (canceled)
